(19) United States
(12) Patent Application Publication
(10) Pub. No.: US 2012/0273948 A1
(43) Pub. Date: Nov. 1, 2012

(54) INTEGRATED CIRCUIT STRUCTURE INCLUDING A COPPER-ALUMINUM INTERCONNECT AND METHOD FOR FABRICATING THE SAME

(75) Inventors: Kuo Hui Su, Taipei City (TW); Yi Nan Chen, Taipei City (TW); Hsien Wen Liu, Luzhu Township (TW)

(73) Assignee: NANYA TECHNOLOGY CORPORATION, Kueishan (TW)

(21) Appl. No.: 13/094,944

(22) Filed: Apr. 27, 2011

(51) Int. Cl. H01L 23/52; H01L 21/768

(52) U.S. Cl. 257/751; 438/643; 257/E23.141; 257/E21.575

(57) ABSTRACT

An integrated circuit structure including a copper-aluminum interconnect with a barrier layer including a titanium nitride layer and a method for fabricating the same are disclosed. The method for fabricating an integrated circuit structure including a copper-aluminum interconnect according to the present invention comprises the steps of providing a copper (Cu) layer; forming a barrier layer connected to the copper layer, wherein the barrier layer comprises a first layer including a tantalum layer and a tantalum nitride layer and a second layer including a titanium nitride layer, the first layer contacts the copper layer and is disposed between the copper layer and the second layer, and the barrier layer has a recess correspondingly above the copper layer; and forming an aluminum (Al) layer disposed in the recess.

### BACKGROUND OF THE INVENTION

1. Technical Field

The present invention relates to an integrated circuit structure including a copper-aluminum interconnect and a method for fabricating the same, and more particularly, to an integrated circuit structure including a copper-aluminum interconnect with a barrier layer including a titanium nitride layer and a method for fabricating the same.

1. Technical Field

In the fabrication of integrated circuit structures, aluminum (Al) and its alloys are widely used for forming electrical connections. However, as device scale continues to be reduced, the number of devices which must be electrically interconnected increases. The increased number of electrical interconnections required for advanced integrated circuit designs necessitates the formation of extremely narrow interconnect leads. The utilization of aluminum and its alloys for high density interconnect formation is limited by the tendency of aluminum to exhibit thermally induced voiding and electromigration. An additional problem of importance associated with aluminum metallurgy is the relatively higher electrical resistance of aluminum alloys compared to other electrically conductive metals.

To overcome the limitations associated with the use of aluminum for electrical interconnects, other metals such as copper (Cu), gold (Au), and silver (Ag) have been proposed as substitutes for aluminum and its alloys. Copper offers a desirable alternative to aluminum, because of its low resistivity. However, copper diffuses readily in materials commonly used in integrated circuit fabrication, such as silicon (Si) and silicon dioxide (SiO₂). This characteristic of copper prohibits the relatively straightforward formation of copper leads in a manner analogous to that used in the formation of aluminum interconnects. Therefore, the implementation of aluminum for the formation of electrical interconnects between aluminum and copper requires that special processes and materials be provided to overcome the problems of diffusion and adhesion associated with the use of copper.

### SUMMARY

One aspect of the present invention provides an integrated circuit structure including a copper-aluminum interconnect to provide an effective barrier to the copper and aluminum diffusion. An integrated circuit structure including a copper-aluminum interconnect according to this aspect of the present invention comprises a copper (Cu) layer, a barrier layer and an aluminum (Al) layer. The barrier layer is connected to the copper layer, wherein the barrier layer comprises a first layer including a tantalum layer and a tantalum nitride layer and a second layer including a titanium nitride layer, the first layer contacts the copper layer and is disposed between the copper layer and the second layer, and the barrier layer has a recess correspondingly above the copper layer. The aluminum (Al) layer is disposed in the recess.

Another aspect of the present invention provides a method for fabricating an integrated circuit structure including a copper-aluminum interconnect to provide an effective barrier to the copper and aluminum diffusion. A method for fabricating an integrated circuit structure including a copper-aluminum interconnect according to this aspect of the present invention comprises the steps of providing a copper (Cu) layer; forming a barrier layer connected to the copper layer, wherein the barrier layer comprises a first layer including a tantalum layer and a tantalum nitride layer and a second layer including a titanium nitride layer, the first layer contacts the copper layer and is disposed between the copper layer and the second layer, and the barrier layer has a recess correspondingly above the copper layer; and forming an aluminum (Al) layer disposed in the recess.

Another aspect of the present invention provides a method for fabricating an integrated circuit structure including a copper-aluminum interconnect to provide an effective barrier to the copper and aluminum diffusion. A method for fabricating an integrated circuit structure including a copper-aluminum interconnect according to this aspect of the present invention comprises the steps of forming a second dielectric layer on a first dielectric layer and a copper layer in the first dielectric layer to form a hole exposing the copper layer; forming a barrier layer covering the hole, wherein the barrier layer is connected to the copper layer and comprises a first layer including a tantalum layer and a tantalum nitride layer and a second layer including a titanium nitride layer, the first layer contacts the copper layer and is disposed between the copper layer and the second layer, and the barrier layer has a recess correspondingly above the copper layer; and forming an aluminum (Al) layer disposed in the recess.

The foregoing has outlined rather broadly the features of the present invention in order that the detailed description of the invention that follows may be better understood. Additional features of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives of the present invention will become apparent upon reading the following description and upon reference to the accompanying drawings in which:

FIG. 1 is a schematic view illustrating a copper-aluminum interconnect according to one embodiment of the present invention;

FIG. 2 and FIG. 3 illustrate a method for fabricating an integrated circuit structure according to one embodiment of the present invention;

FIG. 4 is a flow diagram illustrating a method for fabricating an integrated circuit structure including a copper-aluminum interconnect according to one embodiment of the present invention;

FIG. 5 and FIG. 6 illustrate a method for fabricating a barrier layer according to one embodiment of the present invention; and

FIG. 7 depicts a schematic diagram of plasma oxidation reactor.

### DETAILED DESCRIPTION

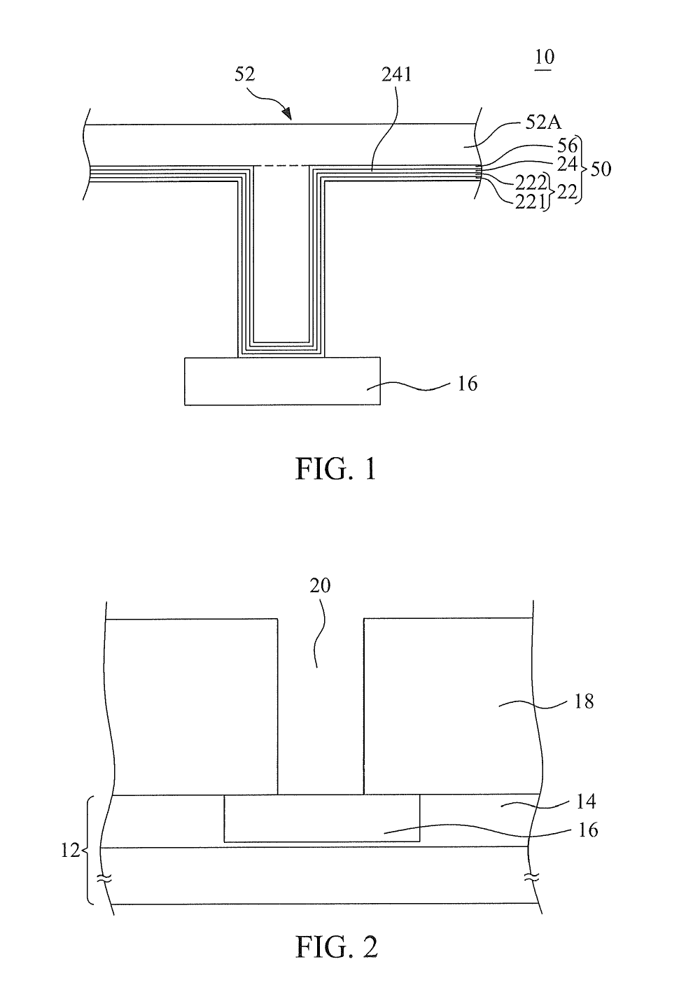

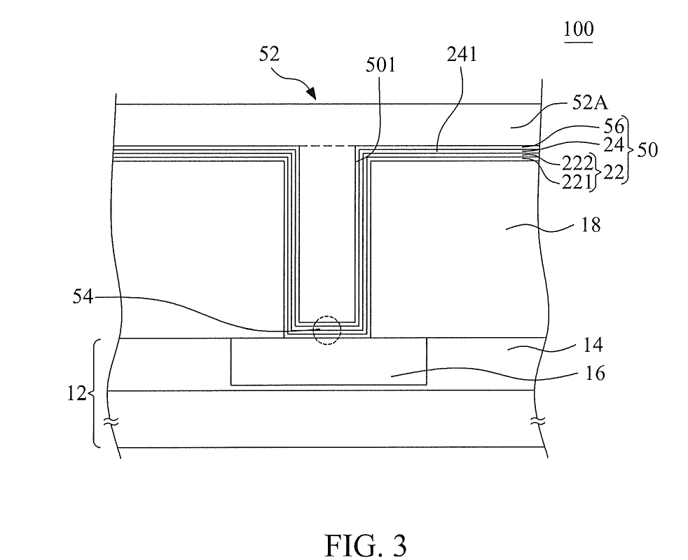

FIG. 1 is a schematic view illustrating a copper-aluminum interconnect according to one embodiment of the present invention. FIG. 2 and FIG. 3 illustrate a method for fabricating an integrated circuit structure according to one embodiment of the present invention. Referring to FIG. 1, the copper-aluminum interconnect 10 comprises a copper (Cu) layer 16, a barrier layer 50 and an aluminum (Al) layer 52, and the barrier layer 50 is connected to the copper (Cu) layer 16 and the aluminum (Al) layer 52.

Referring to FIGS. 1 to 3, in one embodiment of the present invention, the integrated circuit structure 100 includes the copper-aluminum interconnect 10, a first dielectric layer 14 and a second dielectric layer 18. The copper layer 16 is disposed in the first dielectric layer 14, the second dielectric layer 18 is disposed on the first dielectric layer 14 and the copper layer 16 to form a hole 20 exposing the copper layer, and the barrier layer 50 covers the bottom and sidewalls of the hole 20 and is connected to the copper layer 16 to form a recess 501 correspondingly above the copper layer 16.

The barrier layer 50 comprises a first layer 22 including a tantalum layer 221 and a tantalum nitride layer 222 and a second layer 24 including a titanium nitride layer 241. The first layer 22 contacts the copper layer 16 and is disposed between the copper layer 16 and the second layer 24, and the aluminum (Al) layer 52 is disposed in the recess 501.

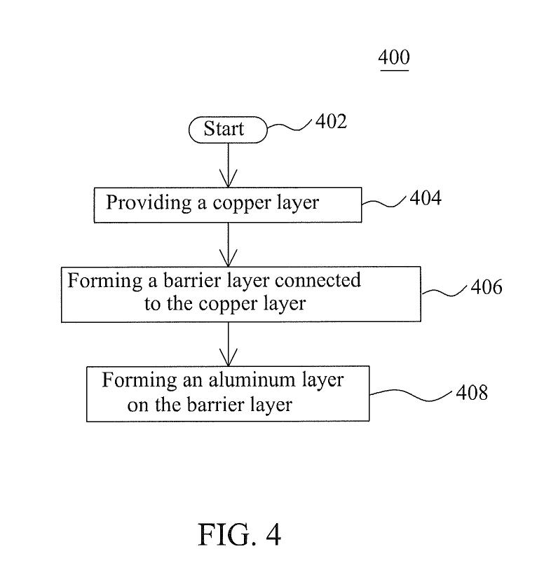

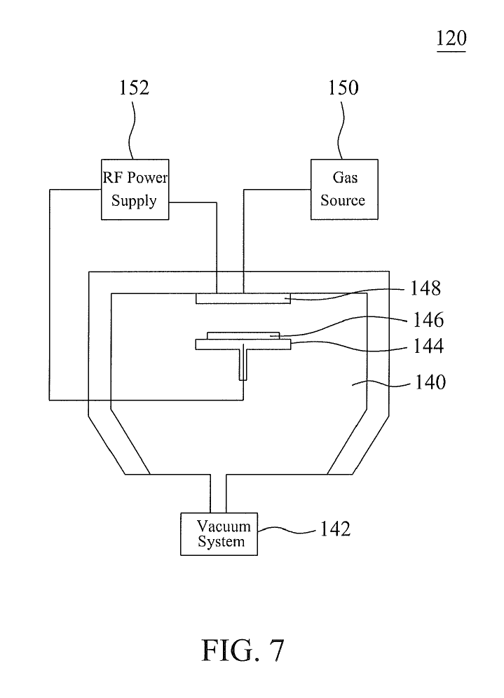

FIG. 4 is a flow diagram illustrating a method 400 for fabricating an integrated circuit structure 100 including a copper-aluminum interconnect 10 according to one embodiment of the present invention. Referring to FIGS. 1 to 4, the method 400 includes processing steps performed upon a substrate 12 such as silicon wafer during fabrication of the integrated circuit structure 100 including a copper-aluminum interconnect 10. Sub-steps and auxiliary procedures (e.g., substrate transfers between processing reactors, process control steps, and the like) are well known in the art and, as such, are omitted herein. At least portions of the method 400 may be performed using processing reactors of an integrated semiconductor substrate processing system. A general description of a suitable processing system 120 is discussed below with reference to FIG. 7.

In one embodiment of the present invention, the second dielectric layer 18 is formed on the substrate 12 including the copper layer 16 in the first dielectric layer 14, and the hole 20 exposing the copper layer 16 is then formed in the second dielectric layer 18 by the photolithographic and etching processes. The substrate 12 may further include a silicon substrate, conductor and insulator below the first dielectric layer 14, which are prepared in advance of the forming of the copper layer 16. Subsequently, the barrier layer 50 is formed inside the hole 20 and on the second dielectric layer 18 (namely, covering the bottom and sidewalls of the hole 20), so as to form the recess 501, and the aluminum (Al) layer 52 is then disposed in the recess 501, as shown in FIG. 3. A cap portion 52A of the aluminum (Al) layer 52 can serve as a bounding pad. The barrier layer 50 covers the bottom surface and the sidewall of the hole 20 to prevent the reciprocal diffusion of copper atoms in the copper layer 16 and aluminum atoms in the aluminum layer 52.

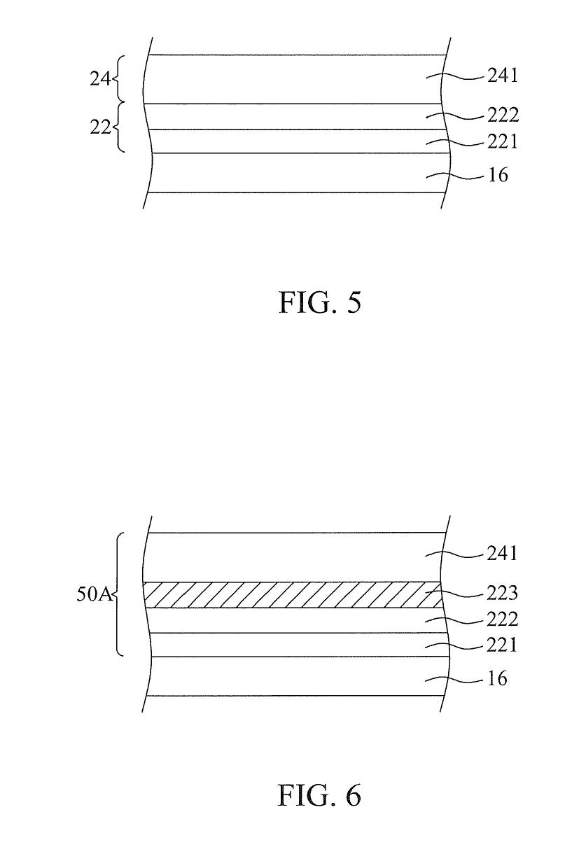

FIG. 5 and FIG. 6 illustrate a method for fabricating a barrier layer 50A according to one embodiment of the present invention, wherein FIG. 5 and FIG. 6 can be considered as close-up views of a selected portion 54 in FIG. 3. Referring to FIG. 5 and FIG. 6, after the hole 20 is formed in the second dielectric layer 18, a tantalum (Ta) layer 221 is formed in the hole 20 and a tantalum nitride (TaN) layer 222 is then formed on the tantalum (Ta) layer 221, forming a first layer 22; and a titanium nitride layer 241 is formed on the tantalum nitride (TaN) layer 222, forming a second layer 24.

In one embodiment of the present invention, the tantalum (Ta) layer 221 is formed on the copper layer 16 by the physical vapor deposition such as the sputtering process, the tantalum nitride (TaN) layer 222 is formed on the tantalum (Ta) layer 221 by the physical vapor deposition such as the reactive sputtering process, and the second layer 24 which is a titanium nitride (TiN) layer is formed on the tantalum nitride (TaN) layer 222 by physical vapor deposition such as the reactive sputtering process. Then, an aluminum layer 52 is formed in the recess 501 by the deposition process. The titanium nitride (TiN) layer 241 is a good aluminum barrier for unbalanced diffusion of aluminum and can efficiently prevent the diffusion of aluminum in the aluminum layer 52.

Preferably, an O₂ stuffing process is performed after the first layer 22 is formed, and a wetting layer 56 such as a titanium layer can be further formed between the second layer 24 and the aluminum layer 52 to enhance the connection of the second layer 24 and the aluminum layer 52.

Referring to FIG. 5 and FIG. 6, a treating process such as an oxygen (O₂) stuffing process is performed in an atmosphere including plasma formed from a gas including oxygen (O₂). The treating process can be considered as an annealing process. The treating process can form a tantalum oxide (TaO) layer 223 (as shown in FIG. 6) on the tantalum nitride (TaN) layer 222.

In one embodiment of the present invention, the treating process comprises the steps of placing the substrate 12 with both the tantalum (Ta) layer 221, the tantalum nitride (TaN) layer 222 and the titanium nitride (TiN) layer 241 thereon in a reaction chamber, transferring the gas into the reaction chamber, and applying RF energy to the reaction chamber to perform a plasma enhanced oxidation process. The plasma is created by subjecting the gas to the RF energy such that oxygen is ionized. Ionized oxygen possesses higher oxidation ability. If not subjected to the RF energy, oxygen will not be ionized until the temperature is greater than 270° C., and such high temperatures increase the diffusion ability of copper in the copper layer 16. In contrast, by subjecting the oxygen to the RF energy, the treating process can be performed at lower temperatures, at least below 100° C. and even as low as room temperature.

Before the treating process, the tantalum nitride (TaN) layer 222 has a column grain structure, which provides diffusion paths for copper atoms in the copper layer 16 through the grain boundary. After the treating process, oxygen atoms exist in the tantalum nitride (TaN) layer 222, i.e., the tantalum nitride (TaN) layer 222 with column grain structure is oxidized during the treating process. In other words, the grain boundary of the column grain structure in the tantalum nitride (TaN) layer 222 is stuffed up by the oxygen atoms, and the ability of the barrier layer 50 to act as a barrier to the reciprocal diffusion of copper in the copper layer 16 and aluminum in the aluminum layer 52 is increased by the treating process.

In addition to stuffing up the grain boundary of the column grain structure in the tantalum nitride (TaN) layer 222, the treating process also forms the tantalum oxide (TaO) layer 223 on the tantalum nitride (TaN) layer 222. The tantalum oxide (TaO) layer 223 does not have the grain boundary because it is not a column structure, i.e., it is able to effectively prevent the reciprocal diffusion of copper in the copper layer 16 and aluminum in the aluminum layer 52.

FIG. 7 depicts a schematic diagram of a plasma oxidation reactor, which may be used to practice portions of the method 400 of FIG. 1. The particular embodiment of the system 120 is illustrative only and should not be used to limit the scope of the invention. It should be understood that the method 200 may be practiced using other processing systems and/or processing reactors.

Referring to FIG. 7, the plasma oxidation reactor 120 has a processing chamber 140 that is generally under a vacuum provided by the vacuum system 142. The processing chamber 140 is equipped with a pedestal 144 that holds a substrate 146 to be processed. The pedestal 144 has an electrode (not shown) embedded therein. A showerhead 148 is located over the pedestal 144. The showerhead 148 has a gas inlet electrode (not shown), and the showerhead 148 allows source gases from the gas source 150 to enter the processing chamber 140. Thus, the showerhead 148 facilitates the formation of plasma from the source gases over the pedestal 144. An RF power supply 152 is coupled to the showerhead 148 via the gas inlet electrode and the pedestal 144 via the electrode in the pedestal. The plasma oxidation process may be carried out at a power of between approximately 1000 and 2000 watts and the processing chamber 140 may be under a pressure of approximately between 5 and 20 mTorr.

Although the present invention and its objectives have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An integrated circuit structure including a copper-aluminum interconnect, comprising:
a copper (Cu) layer;
a barrier layer connected to the copper layer, wherein the barrier layer comprises a first layer including a tantalum layer and a tantalum nitride layer and a second layer including a titanium nitride layer, the first layer contacts the copper layer and is disposed between the copper layer and the second layer, and the barrier layer has a recess correspondingly above the copper layer; and
an aluminum (Al) layer disposed in the recess.

2. The integrated circuit structure including a copper-aluminum interconnect of claim 1, wherein the aluminum layer further comprises a cap portion.

3. The integrated circuit structure including a copper-aluminum interconnect of claim 2, wherein the cap portion serves as a bounding pad.

4. The integrated circuit structure including a copper-aluminum interconnect of claim 1, further comprising a substrate including a first dielectric layer and a second dielectric layer, wherein the copper layer is disposed in the first dielectric layer, the second dielectric layer is disposed on the first dielectric layer and the copper layer and forms a hole exposing the copper layer, and the barrier layer covers the bottom and sidewalls of the hole.

5. The integrated circuit structure including a copper-aluminum interconnect of claim 4, wherein the substrate further includes a silicon substrate, conductor and insulator below the first dielectric layer.

6. The integrated circuit structure including a copper-aluminum interconnect of claim 1, further comprising a wetting layer between the second layer and the aluminum layer.

7. The integrated circuit structure including a copper-aluminum interconnect of claim 6, wherein the wetting layer is a titanium layer.

8. A method for fabricating an integrated circuit structure including a copper-aluminum interconnect, comprising the steps of:
providing a copper (Cu) layer;
forming a barrier layer connected to the copper layer, wherein the barrier layer comprises a first layer including a tantalum layer and a tantalum nitride layer and a second layer including a titanium nitride layer, the first layer contacts the copper layer and is disposed between the copper layer and the second layer, and the barrier layer has a recess correspondingly above the copper layer; and
forming an aluminum (Al) layer disposed in the recess.

9. The method for fabricating an integrated circuit structure including a copper-aluminum interconnect of claim 8, wherein the barrier layer is formed by the sputtering process.

10. The method for fabricating an integrated circuit structure including a copper-aluminum interconnect of claim 8, further comprising a step of stuffing O₂ after forming the first layer.

11. The method for fabricating an integrated circuit structure including a copper-aluminum interconnect of claim 8, wherein the aluminum layer further comprises a cap portion.

12. The method for fabricating an integrated circuit structure including a copper-aluminum interconnect of claim 8, further comprising a step of forming a wetting layer before forming the aluminum layer.

13. A method for fabricating an integrated circuit structure including a copper-aluminum interconnect, comprising the steps of:
forming a second dielectric layer on a first dielectric layer and a copper layer in the first dielectric layer to form a hole exposing the copper layer;
forming a barrier layer covering the hole, wherein the barrier layer comprises a first layer including a tantalum layer and a tantalum nitride layer and a second layer including a titanium nitride layer, the first layer contacts the copper layer and is disposed between the copper layer and the second layer, and the barrier layer has a recess correspondingly above the copper layer; and
forming an aluminum (Al) layer disposed in the recess.

14. The method for fabricating an integrated circuit structure including a copper-aluminum interconnect of claim 13, wherein the barrier layer is formed by the sputtering process.

15. The method for fabricating an integrated circuit structure including a copper-aluminum interconnect of claim 13, further comprising a step of stuffing O₂ after forming the first layer.

16. The method for fabricating an integrated circuit structure including a copper-aluminum interconnect of claim 13, wherein the aluminum layer further comprises a cap portion.

17. The method for fabricating an integrated circuit structure including a copper-aluminum interconnect of claim 13, further comprising a step of forming a wetting layer before forming the aluminum layer.
